(19) United States
(12) Patent Application Publication
(10) Pub. No.: US 2025/0301917 A1
(43) Pub. Date: Sep. 25, 2025

(54) MAGNETIC MEMORY DEVICE AND METHOD OF MANUFACTURING THE SAME

(71) Applicant: SAMSUNG ELECTRONICS CO., LTD., Suwon-si (KR)

(72) Inventors: SUNG CHUL LEE, Suwon-si (KR); KWANG SEOK KIM, Suwon-si (KR); JEONG-HEON PARK, Suwon-si (KR)

(73) Assignee: SAMSUNG ELECTRONICS CO., LTD., Suwon-si (KR)

(21) Appl. No.: 18/894,421

(22) Filed: Sep. 24, 2024

(30) Foreign Application Priority Data
Mar. 21, 2024 (KR) 10-2024-0039156

(51) Int. Cl. H10N 50/85; G11C 11/16; H10B 61/00; H10N 50/01; H10N 50/10; H10N 52/80

(52) U.S. Cl. CPC H10N 50/85; G11C 11/161; G11C 11/1673; G11C 11/1675; H10B 61/22; H10N 50/01; H10N 50/10; H10N 52/80

(57) ABSTRACT

A magnetic memory device may include a conductive line on a substrate and a magnetic tunnel junction pattern on the conductive line. The conductive line includes first and second metal layers alternately stacked in a direction perpendicular to an upper surface of the substrate. The first metal layers include platinum, and the second metal layers include platinum and another metal element other than platinum.

### CROSS-REFERENCE TO RELATED APPLICATIONS

This U.S. non-provisional patent application is based on and claims priority under 35 U.S.C. § 119 to Korean Patent Application No. 10-2024-0039156, filed on Mar. 21, 2024, in the Korean Intellectual Property Office, the entire contents of which are hereby incorporated by reference.

### BACKGROUND

### 1. Field

The disclosure relates to a semiconductor device, and more specifically to a magnetic memory device including a magnetic tunnel junction.

### 2. Description of Related Art

Recently, high-speed and/or low-voltage semiconductor memory devices are in demand to realize efficient power consumption in electronic devices. In this regard, magnetic memory devices have been developed to satisfy such demands. For example, magnetic memory devices have high-speed operational and/or non-volatile characteristics, and thus the magnetic memory devices are spotlighted as a next-generation semiconductor memory device.

Generally, a magnetic memory device may include a magnetic tunnel junction (MTJ). The magnetic tunnel junction may include two magnetic layers and an insulating layer provided between the two magnetic layers. A resistance value of the magnetic tunnel junction may be changed depending on magnetization directions of the two magnetic layers. For example, when the magnetization directions of the two magnetic layers are antiparallel to each other, the magnetic tunnel junction may have a relatively high resistance value. When the magnetization directions of the two magnetic layers are parallel to each other, the magnetic tunnel junction may have a relatively low resistance value. The magnetic memory device may read/write data using a difference between the resistance values of the magnetic tunnel junction. With recent developments in the electronic industry, highly integrated and/or low-power magnetic memory devices have been increasingly demanded. As such, various research is ongoing to satisfy this demand.

### SUMMARY

Aspects of the disclosure provide a spin-orbit torque based magnetic memory device with improved switching characteristics.

According to an aspect of the disclosure, there is provided a magnetic memory device including: a conductive line on a substrate, the conductive line including first metal layers and second metal layers alternately stacked in a direction perpendicular to an upper surface of the substrate; and a magnetic tunnel junction pattern on the conductive line, wherein the first metal layers include platinum, wherein the second metal layers include a first metal element and a second metal element, and wherein the first metal element is platinum and the second metal element is a metal element different than platinum.

According to another aspect of the disclosure, there is provided a magnetic memory device including: a conductive line on a substrate, the conductive line including first metal layers and second metal layers alternately stacked in a direction perpendicular to an upper surface of the substrate; and a magnetic tunnel junction pattern on the conductive line, wherein the first metal layers include platinum (Pt), and wherein the second metal layers include platinum and nickel (PtNi).

According to another aspect of the disclosure, there is provided a magnetic memory device including: a plurality of conductive lines on a substrate; and a magnetic tunnel junction pattern on a first conductive line, among the plurality of conductive lines, the magnetic tunnel junction pattern including: a free magnetic pattern, a pinned magnetic pattern, and a tunnel barrier pattern between the free magnetic pattern and the pinned magnetic pattern, wherein the first conductive line is configured to apply a spin-orbit torque to the magnetic tunnel junction pattern, wherein the first conductive line includes first metal layers and second metal layers, wherein the first metal layers include platinum (Pt), wherein the second metal layers include platinum and nickel (PtNi), and wherein an uppermost first metal layer among the first metal layers is in contact with the free magnetic pattern.

### BRIEF DESCRIPTION OF DRAWINGS

Example embodiments will be more clearly understood from the following brief description taken in conjunction with the accompanying drawings. The accompanying drawings represent non-limiting, example embodiments as described herein.

FIG. 1 is a circuit diagram illustrating a cell array of a magnetic memory device according to embodiments of the disclosure.

FIG. 2 is a circuit diagram schematically illustrating a memory cell of a magnetic memory device according to embodiments of the disclosure.

FIGS. 3A and 3B are cross-sectional views illustrating magnetic tunnel junction patterns constituting the memory cell of FIG. 2.

FIG. 4 is a cross-sectional view of a magnetic memory device according to embodiments of the disclosure.

FIG. 5 is an enlarged view of a conductive line according to embodiments of the disclosure.

FIG. 6 is an enlarged view of a conductive line according to some embodiments of the disclosure.

FIG. 7 shows results of measuring spin hall conductivity according to examples of the disclosure and comparative examples.

### DETAILED DESCRIPTION

Hereinafter, the disclosure will be described in detail by explaining embodiments of the disclosure with reference to the accompanying drawings.

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known after an understanding of the disclosure of this application may be omitted for increased clarity and conciseness.

The features described herein may be embodied in different forms and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

Throughout the specification, when a component is described as being “connected to,” or “coupled to” another component, it may be directly “connected to,” or “coupled to” the other component, or there may be one or more other components intervening therebetween. In contrast, when an element is described as being “directly connected to,” or “directly coupled to” another element, there can be no other elements intervening therebetween. Likewise, similar expressions, for example, “between” and “immediately between,” and “adjacent to” and “immediately adjacent to,” are also to be construed in the same way. As used herein, the term “and/or” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, a first component, a first region, a first layer, or a first section referred to in examples described herein may also be referred to as a second member, a second component, a second region, a second layer, or a second section without departing from the teachings of the examples.

The terminology used herein is for describing various examples only and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof. As used herein, an expression “at least one of” preceding a list of elements modifies the entire list of the elements and does not modify the individual elements of the list. For example, an expression, “at least one of a, b, and c” should be understood as including only a, only b, only c, both a and b, both a and c, both b and c, or all of a, b, and c.

Unless otherwise defined, all terms, including technical and scientific terms, used herein have the same meaning as commonly understood by one of ordinary skill in the art to which this disclosure pertains and based on an understanding of the disclosure of the present application. Terms, such as those defined in commonly used dictionaries, are to be interpreted as having a meaning that is consistent with their meaning in the context of the relevant art and the disclosure of the present application and are not to be interpreted in an idealized or overly formal sense unless expressly so defined herein. The use of the term “may” herein with respect to an example or embodiment (e.g., as to what an example or embodiment may include or implement) means that at least one example or embodiment exists where such a feature is included or implemented, while all example embodiments are not limited thereto.

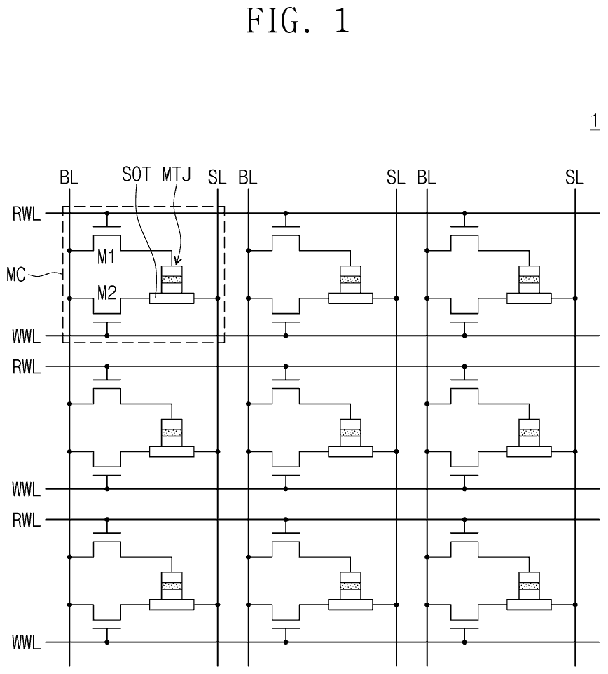

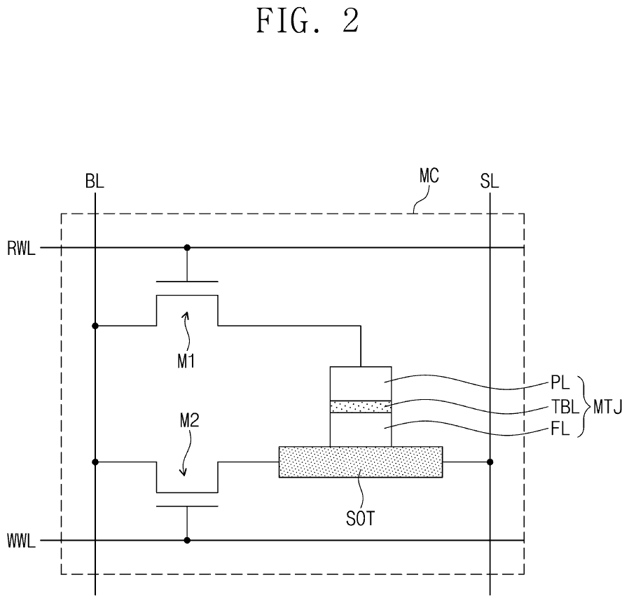

FIG. 1 is a circuit diagram illustrating a cell array of a magnetic memory device according to embodiments of the disclosure. FIG. 2 is a circuit diagram schematically illustrating a memory cell of a magnetic memory device according to embodiments of the disclosure.

Referring to FIGS. 1 and 2, a cell array 1 may include a plurality of write word lines WWL, a plurality of read word lines RWL, a plurality of bit lines BL, a plurality of source lines SL, and a plurality of memory cells MC.

Each of the memory cells MC may include a magnetic tunnel junction pattern MTJ, a conductive line SOT, a first transistor M1, and a second transistor M2. The first transistor M1 may be referred to as a read transistor M1 and the second transistor M2 may be referred to as a write transistor M2. According to an embodiment, the conductive line SOT may be connected to the write transistor M2, and a source line S, among the plurality of source lines SL. For example, the read transistor M1 may include a first source/drain terminal and a second source/drain terminal, and the write transistor M2 may include a third source/drain terminal and a fourth source/drain terminal. Here, the first source/drain terminal may be a source terminal and the second source/drain terminal may be a drain terminal, or vice versa. Also, the third source/drain terminal may be a source terminal and the fourth source/drain terminal may be a drain terminal, or vice versa.

For example, a first end of the conductive line SOT may be connected to the third source/drain terminal of the write transistor M2, and a second end of the conductive line SOT may be connected to a corresponding one of the source lines SL. The magnetic tunnel junction pattern MTJ may be provided on the conductive line SOT. For example, the magnetic tunnel junction pattern MTJ may be provided on the conductive line SOT and between the first end and the second end of the conductive line SOT. Referring to FIG. 2, the magnetic tunnel junction pattern MTJ may include a pinned magnetic pattern PL, a free magnetic pattern FL, and a tunnel barrier pattern TBL between the pinned magnetic pattern PL and the free magnetic pattern FL. The free magnetic pattern FL may be provided between the conductive line SOT and the tunnel barrier pattern TBL, and the pinned magnetic pattern PL may be spaced apart from the free magnetic pattern PL with the tunnel barrier pattern TBL interposed between the pinned magnetic pattern PL and the free magnetic pattern FL. The free magnetic pattern FL may be in contact with a surface of the conductive line SOT. For example, the free magnetic pattern FL may be in contact with a first surface of the conductive line SOT. The first surface of the conductive line SOT may be an upper surface of the conductive line SOT. In an example case in which an in-plane current flows in the conductive line SOT, a spin-orbit torque induced by spin hall effect or Rashba effect may be applied to the free magnetic pattern FL, thereby switching a magnetization direction of the free magnetic pattern FL.

According to an embodiment, the magnetic tunnel junction pattern MTJ may be provided between the read transistor M1 and the conductive line SOT. For example, the magnetic tunnel junction pattern MTJ may be provided between the first source/drain terminal of the read transistor M1 and the conductive line SOT. The magnetic tunnel junction pattern MTJ may be connected to the first source/drain terminal of the read transistor M1. The second source/drain terminal of the read transistor M1 and the fourth source/drain terminal of the write transistor M2 may be commonly connected to a corresponding bit line BL among the bit lines BL.

According to an embodiment, the read transistor M1 may be connected between the magnetic tunnel junction pattern MTJ and the corresponding bit line BL, and a gate electrode of the read transistor M1 may be connected to a corresponding read word line RWL of the read word lines RWL. The read transistor M1 may control the electrical connection between the magnetic tunnel junction pattern MTJ and the corresponding bit line BL. According to an embodiment, the write transistor M2 may be connected between the first end of the conductive line SOT and the corresponding bit line BL, and a gate electrode of the write transistor M2 may be connected to a corresponding write word line WWL among the write word lines WWL. The write transistor M2 may control the electrical connection between the conductive line SOT and the corresponding bit line BL.

The memory cells MC may be arranged in a plurality of rows and a plurality of columns. The memory cells MC in each row may be connected to a corresponding write word line WWL among the write word lines WWL and a corresponding read word line RWL among the read word lines RWL. The memory cells MC in each row may be connected to a corresponding bit line BL among the bit lines BL and a corresponding source line SL among the source lines SL.

The read transistors M1 of the memory cells MC in each row may be commonly connected to the corresponding read word line RWL, and the write transistors M2 of the memory cells MC in each row may be connected to the corresponding write word line WWL. The conductive lines SOT of the memory cells MC in each row may be commonly connected to the corresponding source line SL, and the read and write transistors M1 and M2 of the memory cells MC in each row may be commonly connected to the corresponding bit line BL.

In a write operation on a selected memory cell, the write transistor M2 may be turned on and the read transistor M1 may be turned off through the selected write word line WWL. Accordingly, write current may flow through the conductive line SOT. A direction of the write current may be variously changed depending on voltage conditions applied to the selected bit line BL and the corresponding source line SL.

The write current may apply a spin-orbit torque to the free magnetic pattern FL of the magnetic tunnel junction pattern MTJ. The write current may be an in-plane current. The write current may flow parallel to and adjacent to an interface between the conductive line SOT and the free magnetic pattern FL. While the write current flows, spin current may flow in a direction perpendicular to the interface between the conductive line SOT and the free magnetic pattern FL due to the spin hall effect and Rashba effect, and thus the spin-orbit torque may be applied to the magnetic tunnel junction pattern MTJ. Accordingly, a magnetization direction of the free magnetic pattern FL may be switched to be ‘antiparallel’ (or ‘parallel’) to the magnetization direction of the pinned magnetic pattern PL. For example, the magnetization direction of the free magnetic pattern FL may be switched may be switched to be parallel with the magnetization direction of the pinned magnetic pattern PL but moving or oriented in opposite directions (e.g., “antiparallel”) or the magnetization direction of the free magnetic pattern FL may be switched may be switched to be parallel with the magnetization direction of the pinned magnetic pattern PL and moving or oriented in the same direction (e.g., “parallel”).

In a read operation of a selected memory cell, the read transistor M1 may be turned on and the write transistor M2 may be turned off through the read word line RWL. In a read operation, read current may flow from the selected bit line BL to the corresponding source line SL. The read current may flow through the magnetic tunnel junction pattern MTJ and the conductive line SOT. The read current may flow through the magnetic tunnel junction pattern MTJ in a direction perpendicular to the interface between the conductive line SOT and the magnetic tunnel junction pattern MTJ.

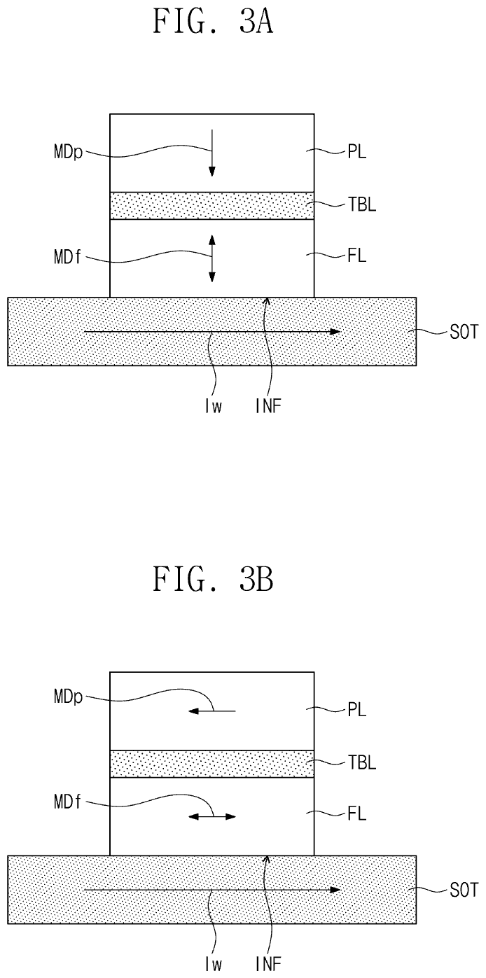

FIGS. 3A and 3B are cross-sectional views illustrating magnetic tunnel junction patterns constituting the memory cell of FIG. 2.

Referring to FIGS. 3A and 3B, the magnetic tunnel junction pattern MTJ may include the free magnetic pattern FL, the tunnel barrier pattern TBL, and the pinned magnetic pattern PL that are sequentially stacked or arranged on the conductive line SOT. The pinned magnetic pattern PL may have a magnetization direction MDp pinned in a first direction, and the free magnetic pattern FL may have a magnetization direction MDf that is capable of being changed to be parallel or antiparallel to the magnetization direction MDp of the pinned magnetic pattern PL. As described with reference to FIGS. 1 and 2, a write current Iw may flow through the conductive line SOT and flow parallel to and adjacent to the interface INF between the conductive line SOT and the free magnetic pattern FL. A spin-orbit torque induced by the write current Iw may be applied to the magnetic tunnel junction pattern MTJ. Accordingly, the magnetization direction of the free magnetic pattern FL may be switched to be antiparallel (or parallel) to the magnetization direction MDp of the pinned magnetic pattern PL.

Referring to FIG. 3A, the magnetization directions MDf and MDp of the free magnetic pattern FL and the pinned magnetic pattern PL may be perpendicular to the interface INF between the spin-orbit torque line SOT and the free magnetic pattern FL. The free magnetic pattern FL and the pinned magnetic pattern PL may have perpendicular magnetic anisotropy. In this case, each of the free magnetic pattern FL and the pinned magnetic pattern PL may include at least one material selected from an intrinsic perpendicular magnetization material and an extrinsic perpendicular magnetization material. The intrinsic perpendicular magnetization material may include a material having a perpendicular magnetization property. For example, the perpendicular magnetization property may be found in the intrinsic perpendicular magnetization material even in the absence of an external factor. The intrinsic perpendicular magnetization material may include at least one material selected from a perpendicular magnetic material having an L1₀ structure, a Cobalt-Platinum (CoPt) of a hexagonal close packed (HCP) lattice structure, and a perpendicular magnetization structure. The intrinsic perpendicular magnetization material may include, but is not limited to, one or more of Cobalt-Iron-Thulium (CoFeTb), Cobalt-Iron-Gadolinium (CoFeGd) and Cobalt-Iron-Dysprosium (CoFeDy). The perpendicular magnetic material having the L1₀ structure may include at least one selected from Iron-Platinum (FePt) of the L1₀ structure, Iron-Palladium (FePd) of the L1₀ structure, Cobalt-Palladium (CoPd) of the L1₀ structure, and CoPt of the L1₀ structure. The perpendicular magnetization structure may include magnetic layers and non-magnetic layers that are alternately and repeatedly stacked. For example, the perpendicular magnetization structure may include at least one selected from (Co/Pt) n, (CoFe/Pt) n, (CoFe/Pd) n, (Co/Pd) n, (Co/Ni) n, (CoNi/Pt) n, (CoCr/Pt) n, and (CoCr/Pd) n (where, n is the number of stacked layers). For example, (Co/Pt) n may mean that there are n Co layers (which are magnetic layers, and n platinum layers (which are non-magnetic layers) alternately and repeatedly stacked. Here, CoNi is Cobalt-Nickel and CoCr is Cobalt-Chromium. The extrinsic perpendicular magnetization material may include a material having an intrinsic horizontal magnetization property or a perpendicular magnetization property caused by an external factor. For example, the extrinsic perpendicular magnetization material may have the perpendicular magnetization property caused by magnetic anisotropy induced by a junction between the tunnel barrier pattern TBL and the free magnetic pattern FL (or the pinned magnetic pattern PL). The extrinsic perpendicular magnetization material may include, for example, CoFeB.

Referring to FIG. 3B, the magnetization direction MDf of the free magnetic pattern FL and the magnetization direction MDp of the pinned magnetic pattern PL may be parallel to the interface INF between the spin-orbit torque line SOT and the free magnetic pattern FL. The free magnetic pattern FL and the pinned magnetic pattern PL may have in-plane magnetic anisotropy. In this case, each of the free magnetic pattern FL and the pinned magnetic pattern PL may include a ferromagnetic material. The pinned magnetic pattern PL may further include an anti-ferromagnetic material that fixes a magnetization direction of the ferromagnetic material in the pinned magnetic pattern PL.

According to some example embodiments, each of the free magnetic pattern FL and the pinned magnetic pattern PL may include a Co-based Heusler alloy. The tunnel barrier pattern TBL may include at least one layer selected from a magnesium (Mg) oxide layer, a titanium (Ti) oxide layer, an aluminum (Al) oxide layer, a magnesium-zinc (Mg—Zn) oxide layer, and a magnesium-boron (Mg—B) oxide layer.

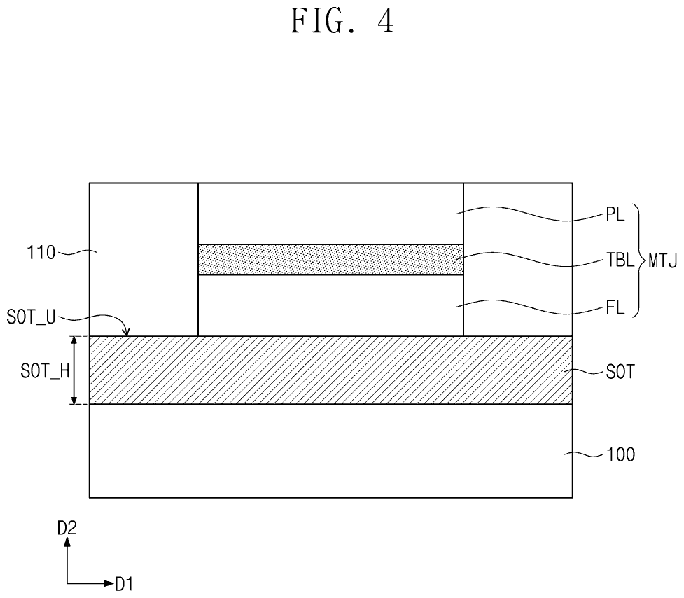

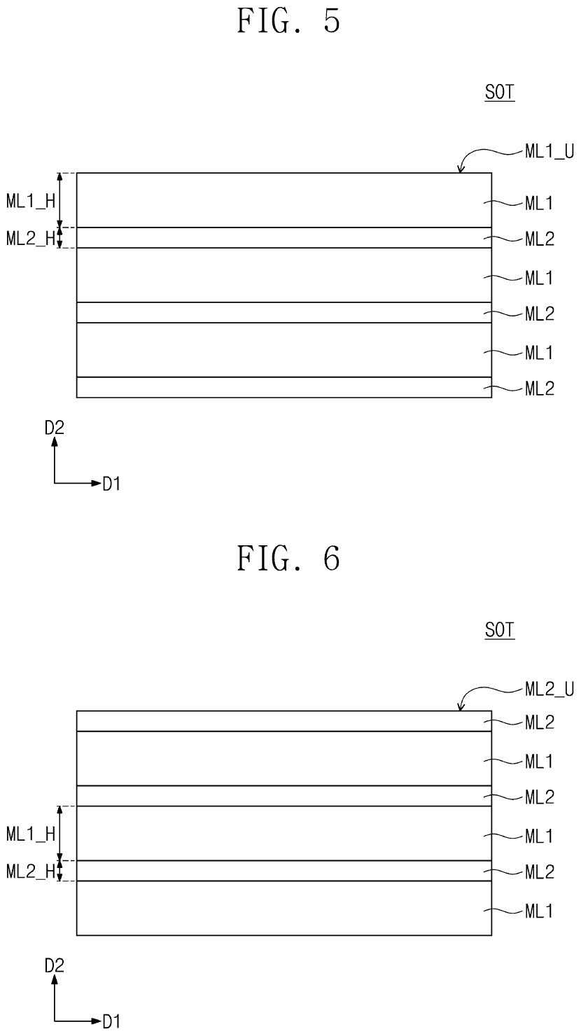

FIG. 4 is a cross-sectional view of a magnetic memory device according to embodiments of the disclosure. FIG. 5 is an enlarged view of a conductive line according to embodiments of the disclosure. For simplicity of explanation, content that overlaps with the magnetic memory device described with reference to FIGS. 1 to 3B will be omitted.

Referring to FIGS. 4 and 5, a conductive line SOT may be provided on the substrate 100. Moreover, a read transistor M1 (shown in FIG. 1) and a write transistor M2 (in FIG. 1) may be provided on the substrate 100. The substrate 100 may be a semiconductor substrate including, but not limited to, a silicon substrate, a germanium substrate, and/or a silicon-germanium substrate.

According to a embodiment, a first end of the conductive line SOT may be electrically connected to the write transistor M2 (shown in FIG. 1), and a second end of the conductive line SOT may be electrically connected to a corresponding source line among the source lines SL (shown in FIG. 1). The conductive line SOT may extend in a first direction D1 parallel to an upper surface of the substrate 100.

Referring to FIG. 5, the conductive line SOT may include first metal layers ML1 and second metal layers ML2. For example, the first metal layers ML1 and the second metal layers ML2 may be alternately stacked in a direction perpendicular to an upper surface of the substrate 100 (e.g., a second direction D2). The conductive line SOT may be configured to apply spin-orbit torque to the magnetic tunnel junction pattern MTJ. According to embodiments of the disclosure, an upper surface ML1_U of the uppermost first metal layer ML1 may be an upper surface SOT_U of the conductive line SOT. FIG. 5 illustrates that the conductive line SOT has a structure in which three first metal layers ML1 and three second metal layers ML2 are alternately stacked, but the disclosure is not limited thereto. As such, the number of first metal layers ML1 and the number of second metal layers ML2 may be different than three. For example, conductive line SOT may have a structure in which three or more first metal layers ML1 and three or more second metal layers ML2 are alternately stacked. According to another embodiment, the number of first metal layers ML1 may be different from the number of second metal layers ML2.

According to an embodiment, a vertical thickness SOT_H of the conductive line SOT may be 20 nm to 50 nm. In an example case in which the vertical thickness SOT_H is greater than 50 nm, integration of the magnetic memory device may be reduced. According to an embodiment, a first vertical thickness ML1_H of each of the first metal layers ML1 and a second vertical thickness ML2_H of each of the second metal layers ML2 may be different from each other. For example, the first vertical thickness ML1_H of each of the first metal layers ML1 may be, for example, 0.5 nm to 10 nm, and the second vertical thickness ML2_H of each of the second metal layers ML2 may be, for example, 0.2 nm to 4 nm. The first vertical thickness ML1_H may be greater than the second vertical thickness ML2_H.

The first metal layers ML1 may include platinum (Pt). The second metal layers ML2 may include PtX, and ‘X’ may be a metal element other than platinum (Pt). The ‘X’ may include a magnetic metal element. For example, the magnetic metal element may include, but is not limited to nickel (Ni). Additionally, the ‘X’ may include a non-magnetic metal element. For example, the non-magnetic metal element may include, but is not limited to, palladium (Pd), manganese (Mn), and gold (Au).

Each of the first metal layers may include platinum (Pt) monomolecular layers. Each of the second metal layers may include PtX monomolecular layers. The number of platinum monomolecular layers may be 3 to 9, and the number of PtX monomolecular layers may be 1 to 2. For example, each of the first metal layers ML1 may include 3 to 9 monomolecular layers of platinum, and each of the second metal layers ML2 may include 1 to 2 monomolecular layers of PtX.

The magnetic tunnel junction pattern MTJ may be provided on the conductive line SOT. The magnetic tunnel junction pattern MTJ may include a pinned magnetic pattern PL, a free magnetic pattern FL, and a tunnel barrier pattern TBL therebetween. The free magnetic pattern FL may be in contact with the uppermost first metal layer of the first metal layers ML1 of the conductive line SOT.

According to an embodiment of the disclosure, the first metal layers ML1 including platinum (Pt) and the second metal layers ML2 including platinum alloy (PtX) may be alternately stacked in a direction perpendicular to the upper surface of the substrate 100 (e.g., the second direction D2) to form the conductive line SOT. Accordingly, the conductive line SOT may have high spin hall conductivity and high spin hall angle. Therefore, a critical current density (Jc) required for switching the magnetic tunnel junction pattern MTJ may be lowered and switching characteristics of the magnetic memory device may be improved.

According to an embodiment of the disclosure, an interlayer insulating layer 110 may be provided on the substrate 100. The interlayer insulating layer 110 may be provided on an upper surface SOT_U of the conductive line SOT and the magnetic tunnel junction pattern MTJ. For example, the interlayer insulating layer 110 may cover the upper surface SOT_U of the conductive line SOT and the magnetic tunnel junction pattern MTJ. For example, the interlayer insulating layer 110 may include oxide, nitride, and/or oxynitride.

FIG. 6 is an enlarged view of a conductive line according to some embodiments of the disclosure. For simplicity of explanation, content that overlaps with the magnetic memory device described with reference to FIGS. 4 and 5 will be omitted.

Referring to FIGS. 4 and 6, the conductive lines SOT may include first metal layers ML1 and second metal layers ML2 alternately stacked in a direction perpendicular to the upper surface of the substrate 100 (e.g., in the second direction D2). According to some embodiments of the disclosure, an upper surface ML2_U of the uppermost second metal layer ML2 may be the upper surface SOT_U of the conductive lines SOT. However, the disclosure is not limited thereto, and as such, according to another embodiment, an upper surface of the uppermost second metal layer ML1 may be the upper surface SOT_U of the conductive lines SOT. FIG. 6 illustrates that the conductive line SOT has a structure in which three first metal layers ML1 and three second metal layers ML2 are alternately stacked but the disclosure is not limited thereto. The conductive line SOT may have a structure in which three or more first metal layers ML1 and three or more second metal layers ML2 are alternately stacked.

The first metal layers ML1 may include platinum (Pt). The second metal layer ML2 may include PtX, and ‘X’ may be a metal element other than platinum (Pt). The ‘X’ may include a magnetic metal element, for example, nickel (Ni). Additionally, the ‘X’ may include a non-magnetic metal element, for example, palladium, manganese, and gold (Pd, Mn, Au). Each of the first metal layers ML1 may include platinum (Pt) monomolecular layers. Each of the second metal layers ML2 may include PtX monomolecular layers. The number of platinum monomolecular layers may be 3 to 9, and the number of PtX monomolecular layers may be 1 to 2. That is, each of the first metal layers ML1 may include 3 to 9 monomolecular layers of platinum, and each of the second metal layers ML2 may include 1 to 2 monomolecular layers of PtX.

The magnetic tunnel junction pattern MTJ may be provided on the conductive line SOT. The magnetic tunnel junction pattern MTJ may include a pinned magnetic pattern PL, a free magnetic pattern FL, and a tunnel barrier pattern TBR therebetween. The free magnetic pattern FL may be in contact with the uppermost second metal layer of the second metal layers ML2 of the conductive line SOT.

According to an embodiment of the disclosure, the first metal layers ML1 including platinum (Pt) and the second metal layers ML2 including platinum alloy (PtX) may be formed by being alternately stacked in a direction perpendicular to the upper surface of the substrate 100 (e.g., the second direction D2). Accordingly, the conductive line SOT may have high spin hall conductivity and high spin hall angle. Therefore, a critical current density (Jc) required for switching of the magnetic tunnel junction pattern MTJ may be lowered and switching characteristics of the magnetic memory device may be improved.

Hereinafter, with reference to FIGS. 4 and 5, a method of manufacturing a magnetic memory device according to embodiments of the disclosure will be described.

Referring to FIGS. 4 and 5, a conductive line SOT may be formed on the substrate 100. For example, the method of forming the conductive line SOT may include alternatively providing the first metal layer ML1 and the second metal layer ML2 on the substrate 100. For example, the method may include sequentially and alternately depositing the first metal layer ML1 and the second metal layer ML2 on the substrate 100. The first metal layer ML1 and the second metal layer ML2 may be formed using a chemical vapor process and/or a physical vapor deposition process. For example, the physical vapor deposition process may include, but is not limited to a sputtering deposition process.

The magnetic tunnel junction pattern MTJ may be formed on the conductive line SOT. For example, forming the magnetic tunnel junction pattern MTJ may include forming a magnetic tunnel junction layer on the conductive line SOT and patterning the magnetic tunnel junction layer. For example, forming the magnetic tunnel junction layer may include sequentially depositing a free magnetic layer, a tunnel barrier layer, and a pinned magnetic layer on the conductive line SOT. The free magnetic layer, the tunnel barrier layer, and the pinned magnetic layer may be sequentially etched by the patterning process, and accordingly, the free magnetic pattern FL, the tunnel barrier pattern TBL, and the pinned magnetic pattern PL may be formed.

According to an embodiment, an interlayer insulating layer 110 may be formed on the substrate 100. The interlayer insulating layer 110 may be provided on the conductive line SOT and the magnetic tunnel junction pattern MTJ. For example, the interlayer insulating layer 110 may cover the conductive line SOT and the magnetic tunnel junction pattern MTJ.

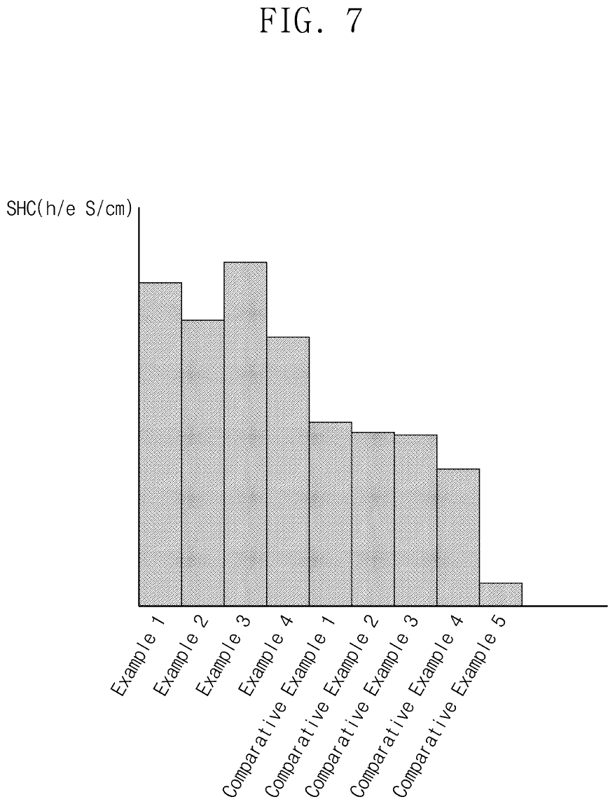

FIG. 7 shows results of measuring spin hall conductivity (SHC) according to examples and comparative examples of the disclosure.

### Example 1

Example 1 illustrates a scenario in which three first metal layers ML1 and three second metal layers ML2 were sequentially and alternately deposited through a physical vapor deposition process. Each of the first metal layers ML1 was deposited to have three platinum (Pt) monomolecular layers. Each of the second metal layers ML2 was deposited to have one PtNi monomolecular layer to manufacture a conductive line SOT. A first vertical thickness ML1_H of each of the first metal layers ML1 was 6 nm, and a second vertical thickness ML2_H of each of the second metal layers ML1 was 1 nm. A vertical thickness of the conductive line was 21 nm.

### Example 2

Example 2 illustrates a scenario in which the second metal layers ML2 were manufactured in substantially the same manner as Example 1, except that each of the second metal layers ML2 had one PtPd monomolecular layer.

### Example 3

Example 3 illustrates a scenario in which the second metal layers ML2 were manufactured in substantially the same manner as Example 1, except that each of the second metal layers ML2 had one PtMn monomolecular layer.

### Example 4

Example 4 illustrates a scenario in which the second metal layers ML2 were manufactured in substantially the same manner as Example 1, except that each of the second metal layers ML2 had one PtAu monomolecular layer.

### Comparative Example 1

In a Comparative Example 1, a conductive line SOT was manufactured by depositing platinum (Pt) monomolecular layers through a physical vapor deposition process. A vertical thickness SOT_H of the conductive line SOT was 21 nm.

### Comparative Example 2

In a Comparative Example 2, a conductive line SOT was manufactured by depositing PtNi monomolecular layers through a physical vapor deposition process. A vertical thickness SOT_H of the conductive line SOT was 21 nm.

Comparative Example 3

In a Comparative Example 2, a conductive line SOT was manufactured by depositing PtPd monomolecular layers through a physical vapor deposition process. A vertical thickness SOT_H of the conductive line SOT was 21 nm.

Comparative Example 4

In a Comparative Example 4, a conductive line SOT was manufactured by depositing PtAu monomolecular layers through a physical vapor deposition process. A vertical thickness SOT_H of the conductive line SOT was 21 nm.

Comparative Example 5

In a Comparative Example 4, a conductive line SOT was manufactured by depositing PtMn monomolecular layers through a physical vapor deposition process. A vertical thickness SOT_H of the conductive line SOT was 21 nm.

FIG. 7 shows results of a measurement of the spin hall conductivity (SHC) of the above examples and comparative examples. Referring to FIG. 7, it may be seen that Examples 1 to 4 have higher spin hall conductivity than Comparative Example 1. That is, in an example case in which the first metal layers ML1 and the second metal layers ML2 are alternately stacked, the spin Hall conductivity is higher than an example case in which the conductive line SOT is formed with only a single platinum (Pt).

In addition, in an example case in which the first metal layers ML1 and the second metal layers ML2 are alternately stacked, the spin hall conductivity is higher than an example case in which the conductive line SOT is composed of only a platinum alloy layer, by comparing Examples 1 to 4 with Comparative Examples 2 to 5.

According to an embodiment of the disclosure, the conductive line may be provided under the magnetic tunnel junction pattern, and the conductive line may include the first metal layers and the second metal layers alternately stacked in the direction perpendicular to the upper surface of the substrate. The first metal layers may include platinum (Pt), the second metal layers may include PtX, where ‘X’ may be a metal element other than platinum (Pt), and where ‘X’ may include at least one of nickel, palladium, gold, and manganese.

The first metal layers containing platinum and the second metal layers containing platinum alloy may be alternately stacked to form the conductive line. Accordingly, the conductive line may have high spin hall conductivity. Therefore, the critical current density (Jc) required for switching of the magnetic tunnel junction pattern may be lowered. That is, the switching characteristics of the magnetic memory device may be improved.

While embodiments are described above, a person skilled in the art may understand that many modifications and variations are made without departing from the spirit and scope of the disclosure defined in the following claims. Accordingly, the example embodiments of the disclosure should be considered in all respects as illustrative and not restrictive, with the spirit and scope of the disclosure being indicated by the appended claims.

What is claimed is:

1. A magnetic memory device comprising:
a conductive line on a substrate, the conductive line comprising first metal layers and second metal layers alternately stacked in a direction perpendicular to an upper surface of the substrate; and
a magnetic tunnel junction pattern on the conductive line,
wherein the first metal layers comprise platinum, wherein the second metal layers comprise a first metal element and a second metal element, and
wherein the first metal element is platinum and the second metal element is a metal element different than platinum.

2. The magnetic memory device of claim 1, wherein a first vertical thickness of each of the first metal layers and a second vertical thickness of each of the second metal layers are different from each other.

3. The magnetic memory device of claim 1, wherein the conductive line is configured to apply a spin-orbit torque to the magnetic tunnel junction pattern.

4. The magnetic memory device of claim 1, wherein the magnetic tunnel junction pattern comprises:
a free magnetic pattern,
a pinned magnetic pattern, and
a tunnel barrier pattern between the free magnetic pattern and the pinned magnetic pattern, and
wherein an uppermost first metal layer among the first metal layers and the free magnetic pattern are in contact with each other.

5. The magnetic memory device of claim 1, wherein the conductive line comprises a magnetic metal element.

6. The magnetic memory device of claim 1, wherein each of the first metal layers comprises first monomolecular layers including platinum,
wherein each of the second metal layers comprises second monomolecular layers including the first metal element and the second metal element.

7. The magnetic memory device of claim 1, wherein the second metal element is a magnetic metal element.

8. The magnetic memory device of claim 1, wherein the second metal element comprises at least one of nickel, palladium, manganese, or gold.

9. The magnetic memory device of claim 6, wherein a number of first monomolecular layers is 3 to 9, and
wherein a number of second monomolecular layers is 1 or 2.

10. The magnetic memory device of claim 1, further comprising an interlayer insulating layer on the substrate,
wherein the interlayer insulating layer is provided on an upper surface of the conductive line and the magnetic tunnel junction pattern.

11. The magnetic memory device of claim 1, wherein a vertical thickness of the conductive line is 20 nm to 50 nm.

12. A magnetic memory device comprising:
a conductive line on a substrate, the conductive line comprising first metal layers and second metal layers alternately stacked in a direction perpendicular to an upper surface of the substrate; and
a magnetic tunnel junction pattern on the conductive line,
wherein the first metal layers comprise platinum (Pt), and
wherein the second metal layers comprise platinum and nickel (PtNi).

13. The magnetic memory device of claim 12, wherein a first vertical thickness of each of the first metal layers and a second vertical thickness of each of the second metal layers are different from each other.

14. The magnetic memory device of claim 13, wherein the first vertical thickness is greater than the second vertical thickness.

15. The magnetic memory device of claim 12, wherein each of the first metal layers comprises Pt monomolecular layers, and
wherein each of the second metal layers comprises PtNi monomolecular layers.

16. The magnetic memory device of claim 15, wherein a number of the Pt monomolecular layers is 3 to 9,
wherein a number of the PtNi monomolecular layers is 1 or 2.

17. A magnetic memory device comprising:
a conductive line on a substrate; and
a magnetic tunnel junction pattern on the conductive line comprising:
a free magnetic pattern,
a pinned magnetic pattern, and
a tunnel barrier pattern between the free magnetic pattern and the pinned magnetic pattern, wherein the conductive line is configured to apply a spin-orbit torque to the magnetic tunnel junction pattern,
wherein the conductive line comprises first metal layers and second metal layers,
wherein the first metal layers comprise platinum (Pt),
wherein the second metal layers comprise platinum and nickel (PtNi), and
wherein an uppermost first metal layer among the first metal layers is in contact with the free magnetic pattern.

18. The magnetic memory device of claim 17, wherein a first vertical thickness of each of the first metal layers is greater than a second vertical thickness of each of the second metal layers.

19. The magnetic memory device of claim 17, wherein each of the first metal layers comprises Pt monomolecular layers, and
wherein each of the second metal layers comprises PtNi monomolecular layers.

20. The magnetic memory device of claim 17, wherein a first vertical thickness of each of the first metal layers is 0.5 nm to 10 nm, wherein a second vertical thickness of each of the second metal layers is 0.2 nm to 4 nm, and
wherein the first vertical thickness is greater than the second vertical thickness.
